(19) United States
(12) Patent Application Publication
(10) Pub. No.: US 2011/0156225 A1
(43) Pub. Date: Jun. 30, 2011

(54) SEMICONDUCTOR DEVICE AND METHOD OF MANUFACTURING THE SAME

(75) Inventors: Hiroshi Hozoji, Hitachiota (JP); Toshiaki Morita, Hitachi (JP); Yusuke Yasuda, Hitachi (JP); Chiko Yorita, Fujisawa (JP); Yuji Shirai, Kanagawa (JP)

(73) Assignee: RENESAS ELECTRONICS CORPORATION, Kanagawa (JP)

(21) Appl. No.: 13/062,565

(22) PCT Filed: Jul. 31, 2009
(86) PCT No.: PCT/JP2009/063688

§ 371 Date: Mar. 7, 2011

(30) Foreign Application Priority Data
Sep. 10, 2008 (JP) 2008-232105

(51) Int. Cl. H01L 23/552; H01L 21/56

(52) U.S. Cl. 257/659; 438/126; 257/E23.114; 257/E21.502

(57) ABSTRACT

A semiconductor device achieving both electromagnetic wave shielding property and reliability in a heating process upon mounting electronic components. In the semiconductor device, mount devices 5 and 6 mounted on a main surface of a circuit board 1 are provided, the mount devices 5 and 6 are electrically connected to a wiring pattern 4 at the main surface of the circuit board 1, a sealant 7 of an insulating resin is formed to seal the mount devices 5 and 6, metal particles are applied to a surface of the sealant 7, and the metal particles applied are sintered, thereby forming an electromagnetic shielding layer 2, and electrically connecting the electromagnetic shielding layer 2 to a ground pattern 3 of the circuit board 1.

### TECHNICAL FIELD

The present invention relates to a semiconductor device and a method of manufacturing the same, and more particularly relates to formation of a shield layer of a semiconductor device which mounts semiconductor-mounting electronic components requiring a shielding structure for avoiding adverse effects of electromagnetic noise from ambient radio waves or semiconductors and/or a high-frequency semiconductor element requiring shielding of noise generated from itself.

### BACKGROUND ART

A packaging (mounting) structure of electronic components including semiconductors will be explained taking a mobile phone as an example.

A packaging board inside a mobile phone mounts various electronic components. Functions of the board mainly have the following configuration.

A baseband portion formed of: an RF (Radio frequency) portion which receives high-frequency waves from base stations by an antenna and lowers their frequency to a processable frequency and amplifies the same to transferrable radio waves; a CPU (Central Processing Unit) which processes received signals; various application processors which process images, voice, etc.; and a storage device (memory), etc.

Frequencies of transferred/received radio waves to be processed by the RF portion are as follows.

Frequencies of respective communications standards in Japan are: PDC (Personal Digital Cellular) of 800 MHz band; cdmaOne (Code Division Multiple Access One) of 1.5 GHz band; CDMA2000 of 1.7 GHz band; and W-CDMA (Wideband Code Division Multiple Access) of 2100 MHz band.

Also, a global communications system around Europe of GSM (Global System for Mobile Communications) system uses frequencies of 900 MHz band and 1800 to 1900 MHz band, and a system used in United States of D-AMPS (Digital Advanced Mobile Phone System) uses 800 MHz band and 900 MHz band.

A component which amplifies transferred waves for transferring radio waves from a telephone to a base station to obtain each frequency of these frequencies is a power amplifier. There are various types of such a power amplifier compatible to various communication systems/frequencies combined by selecting the above-mentioned frequencies in accordance with usages and/or regions.

Since output characteristics of a transistor which amplifies radio waves in the power amplifier are nonlinear, noise of second harmonic wave and third harmonic wave of input frequency occurs in an output of a portion where efficiency is desired to be ensured. While a circuit design is made so that this noise to be on the transferred wave is removed by a filter, noise is generated from the power amplifier part itself and it may have adverse effects to electronic components including peripheral semiconductors.

Regarding high-frequency components having wireless functions, to explain with taking Japanese mobile phones as examples, in addition to the power amplifier, there are Near Field Communications by infrared ways or Bluetooth, a TV waves tuner for One Seg of 400 MHz band, an FM/AM radio wave tuner etc., and it is predicted that various wireless systems such as WiFi (Wireless Fidelity) etc. will be mounted in the future. Therefore, it is necessary to consider mutual influence of electromagnetic noise generated from these electronic components.

Next, on the baseband portion, a CPU being responsible for a main body function of the telephone; various application processors handling a main storage device, image, video, music, security etc., various memories; and/or passive equipments are packaged. Clock frequency of these application processors is increasing year by year.

When packaging separately from external memories, instruction errors due to disturbance noise are prone to occur. In view of preventing the errors, reducing design load, reducing power consumption, and reducing packaging area, structures of packaging with stacking processors and memories are being increased.

Current floes in a bonding wire when exchanging high-speed signals between an application processor and a memory, and a magnetic field and electrical field (noise) are generated on the line path as the wire portion becomes an antenna and electromagnetic waves are generated.

Regarding noise countermeasures of a packaging board of a mobile phone, there is a margin in arrangement of semiconductor parts to each other, and, if parts to be concerned about noise interference can be mounted separately, normally, a metal cap is mounted in a large area per function block unit so that a shielding effect is provided.

Meanwhile, in the trend of increasing functions and introducing ultra thin forms of mobile phones in recent years, the design is made to eliminate dead space so that a sterically mounting arrangement is obtained by packing components in available space. In such a design, ensuring mounting areas for large components, even for a shield cap which is indispensable, is difficult.

However, removing the metal cap and putting a semiconductor for high-speed communications, a semiconductor for high-speed image processing, and/or a power amplifier of an RF circuit adjacent as a single package as it is without a shield has had problems of posing erroneous operations due to noise as mentioned above.

For example, regarding electronic components for the purpose of individual shielding, as described in Japanese Patent Application Laid-Open Publication No. 2005-322752 (Patent Document 1), a general structure is made such that a metal cap is placed on a mounting board with respect to a module in which ICs and/or passive components are mounted on a board.

Meanwhile, a resin sealing is not made inside the cap in the structure, and there has been a problem of a difficulty in mass production about changing a resin molding process to the metal cap structure as a cost of the metal cap is higher than a large semiconductor PKG formed by resin molding. To perform an electromagnetic shielding at a low cost, it is preferable to use currently-used packaging configurations and processes.

Also, there are mounting structures not using a metal cap described in Japanese Patent No. 3718131 (Patent Document 2) and Japanese Patent Application Laid-Open Publication No. 2005-109306 (Patent Document 3). The structure has: semiconductor elements on one surface of a board; an insulating resin formed to seal the semiconductor elements; and a metal thin film formed on a surface of the resin, and the metal film is electrically connected to a wiring pattern formed to the board. The metal thin film to be formed on the insulating resin surface can be formed in a single-layer or a multi-layer manner by plating using gold, silver, copper, and/or nickel etc.

### Prior Art Documents

### Patent Documents

### Patent Document 1: Japanese Patent Application Laid-Open Publication No. 2005-322752

### Patent Document 2: Japanese Patent No. 3718131

### Patent Document 3: Japanese Patent Application Laid-Open

Publication No. 2005-109306

### DISCLOSURE OF THE INVENTION

### Problems to be Solved by the Invention

Meanwhile, while currently-used packaging configurations and processes can be used in mounting structures not using a metal cap, to obtain a sufficient shielding effect, it is effective to lower a sheet resistance by introducing a multi-layer manner but necessities to go through a plurality of plating processes due to the multi-layer manner arises, and thus there has been a problem of a significant increase in cost.

Further, to obtain a sufficient shielding effect by a single layer, it is necessary to make a thickness of the shielding layer large but, as described in Patent Document 3, when using a nickel plating, there has been a problem of generating cracks at the plating portion upon heating when a plating thickness is larger than or equal to 3 μm.

Cracks of metal films upon package heating are predicted to occur when the board on which semiconductor elements are mounted and/or the insulating resin absorbs moisture depending on its storage state and the moisture abruptly vaporizes and expands at an interface of the insulating resin and the metal film in the heating step.

Accordingly, as a method of preventing the cracks of the metal film during heating without losing a shielding property of the metal film, it is considered to be effective to provide fine holes through which moisture vapor upon heating can pass and which can shield electromagnetic waves.

Consequently, a preferred aim of the present invention is, in mounting of electronic components required to be in a high-density mounting, to provide a semiconductor device and a method of manufacturing the same capable of manufacturing a package with an electromagnetic wave noise shield at a low cost with maintaining reliability in a heating step by using a conventional semiconductor assembly process without having adverse effects of noise from other semiconductors, and no noise of itself is released to the outside.

The above and other preferred aims and novel characteristics of the present invention will be apparent from the description of the present specification and the accompanying drawings.

### Means for Solving the Problems

The typical ones of the inventions disclosed in the present application will be briefly described as follows.

More specifically, a summary of the typical one is that a metal plating film is formed on a pre-processing layer formed only to a top surface of a sealant using high-pressure CO₂ in a state in which a back surface of a wiring board is protected, and the metal plating film is electrically connected to a through-hole for ground connection connected to an end portion of a ground wiring layer on a side surface of the wiring board or an end portion of the ground wiring layer.

### EFFECTS OF THE INVENTION

The effects obtained by typical aspects of the present invention will be briefly described below.

More specifically, an effect obtained by the typical one is that an electromagnetic shielding layer formed of a metal sintered compact has fine holes in a thin-film layer so that moisture vapor from an insulating resin layer and/or a circuit board in a manufacturing process of a semiconductor device is easily released from an inside to an outside of the metal thin film, thereby preventing exfoliation of the electromagnetic shielding layer at an interface of the sealant and the metal thin film and preventing cracks of the electromagnetic shielding layer of the metal thin film.

Also, the metal thin film can be formed without drastic changes in a conventional manufacturing process of a semiconductor device.

### BRIEF DESCRIPTIONS OF THE DRAWINGS

FIG. 1 is a perspective view of an exterior of a semiconductor device according to an embodiment of the present invention;

FIG. 2 is a schematic diagram of a cross-sectional view of the semiconductor device according to the embodiment of the present invention;

FIGS. 3A and 3B are diagrams illustrating wiring layouts of a four-layer circuit board of the semiconductor device according to the embodiment of the present invention;

FIGS. 4A and 4B are diagrams illustrating wiring layouts of the four-layer circuit board of the semiconductor device according to the embodiment of the present invention;

FIG. 5 is an example of an observation by a scanning electron microscope of an electromagnetic shielding layer of the semiconductor device according to the embodiment of the present invention;

FIG. 6 is a diagram illustrating a relationship of a diameter of holes of a shielding layer to a level of electromagnetic waves and a permeation rate of moisture vapor measured through the shielding layer;

FIGS. 7A to 7G are diagrams illustrating a manufacturing method of the semiconductor device according to the present invention; and

FIGS. 8A to 8F are diagrams illustrating a manufacturing method of the semiconductor device according to the present invention.

### BEST MODE FOR CARRYING OUT THE INVENTION

Hereinafter, embodiments of the present invention will be described in detail with reference to the accompanying drawings. Note that components having the same function are denoted by the same reference symbols throughout the drawings for describing the embodiment, and the repetitive description thereof will be omitted.

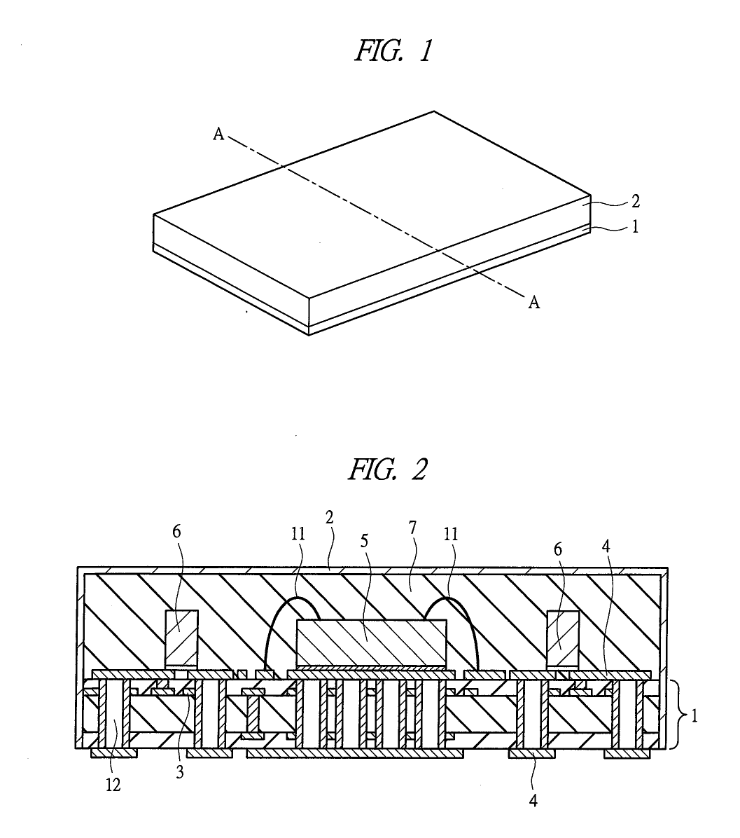

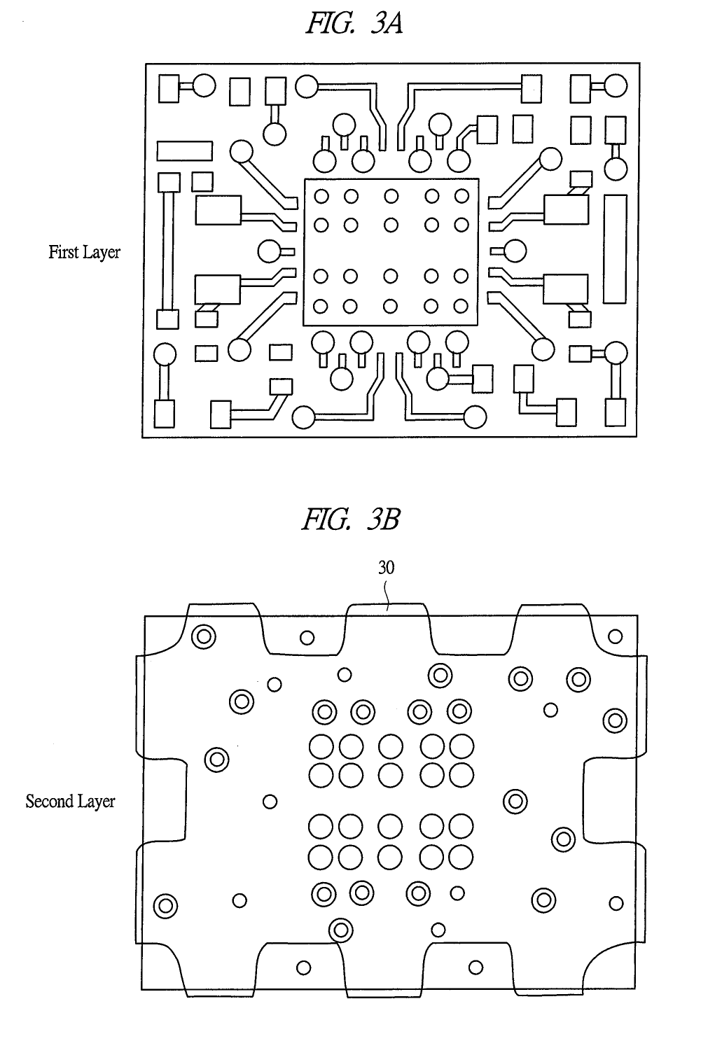

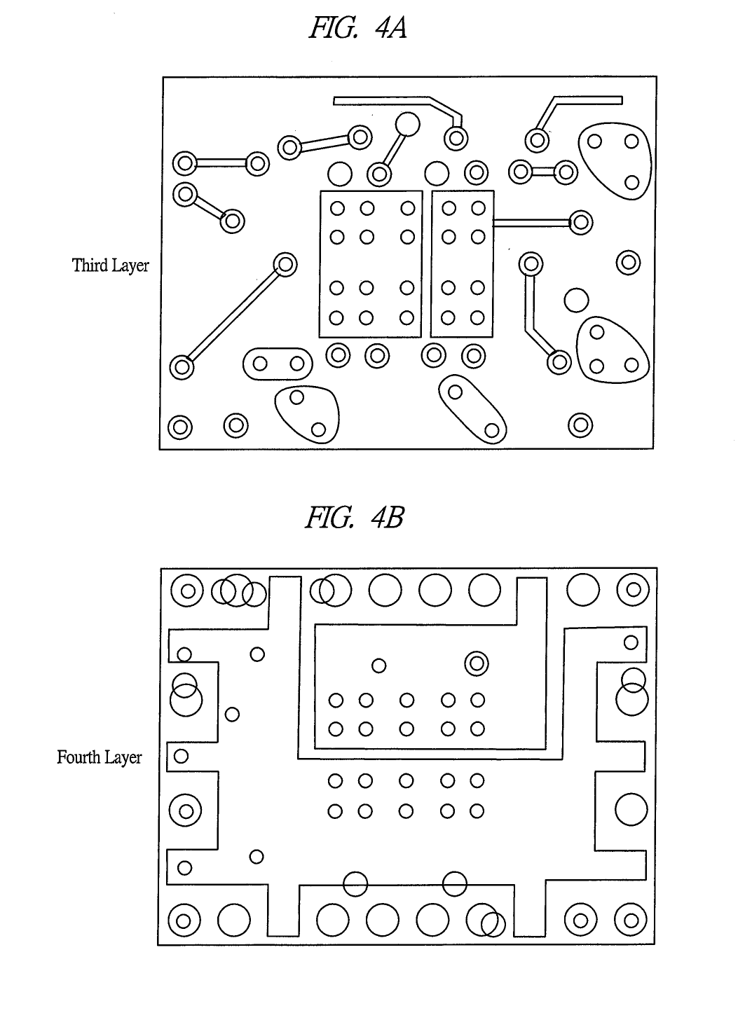

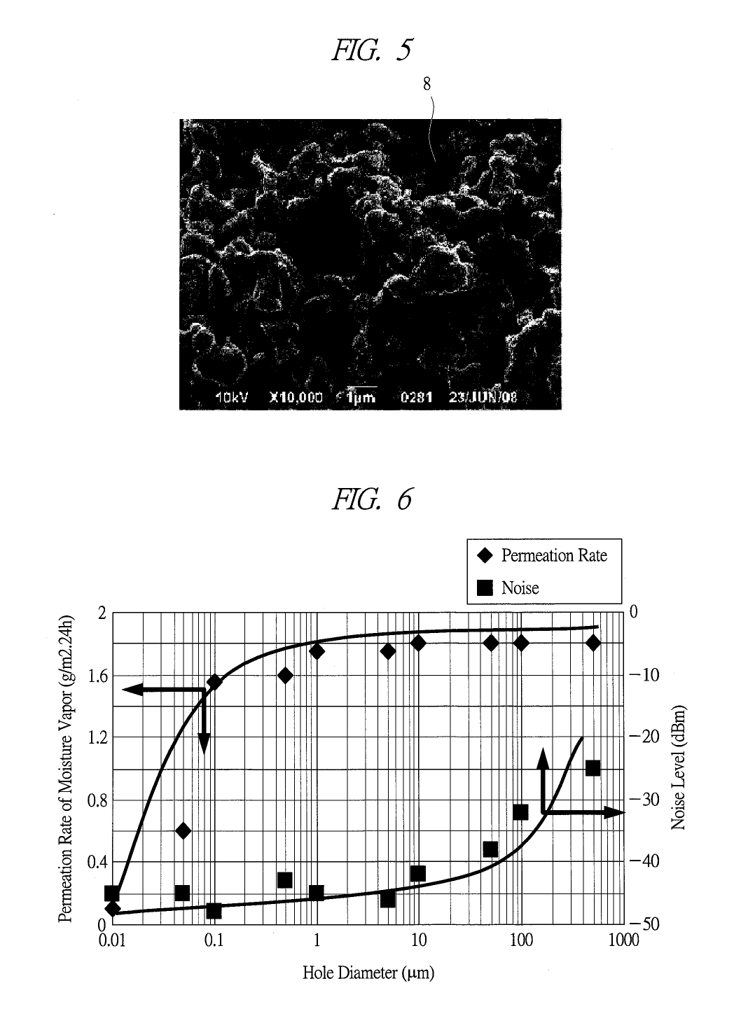

With reference to FIGS. 1 to 5, a configuration of a semiconductor device according to an embodiment of the present invention will be described. FIG. 1 is a perspective view of an exterior of the semiconductor device according to the embodiment of the present invention, and FIG. 2 is a schematic diagram of a cross-sectional view of the semiconductor device according to the embodiment of the present invention, illustrating an A-A cross section of FIG. 1. FIGS. 3A to 4B are diagrams illustrating wiring layouts of a four-layer circuit board of the semiconductor device according to the embodiment of the present invention. FIG. 5 is an example of an observation by a scanning electron microscope of an electromagnetic shielding layer of the semiconductor device according to the embodiment of the present invention.

In FIG. 1, a package of electronic components which is a semiconductor device has an electromagnetic shielding layer 2 formed on a circuit board 1 formed of a multilayer board.

In FIG. 2, to an inside layer and an outside layer of the circuit board 1, at least two or more layers of a ground pattern 3 and a wiring pattern 4 are formed. Further, to the circuit board 1, via holes 12 are formed, making electrical connections between layers. In the example illustrated in FIG. 2, an example of a four-layer board is illustrated.

Also, in the package of electronic components, mount devices 5 and 6 (semiconductor integrated circuit elements like IC, chip resistor, chip capacitor, etc.) are mounted to a top surface of the circuit board having the ground pattern 3 on the wiring pattern 4 using plating (not illustrated) and/or wires 11 etc.

Meanwhile, the package of electronic components mounts the wiring pattern 4 at a bottom surface of the circuit board 1 positioned on the opposite side of the mount devices 5 and 6 and a mother board (not illustrated) by plating, and the package of electronic components is used being conducted with the mother board.

To the top surface of the circuit board to which the mount devices 5 and 6 are mounted, a sealant 7 is formed of an insulating resin of an epoxy resin etc. containing a mineral filler and, further, an electromagnetic shielding layer 2 is formed to a surface of the sealant 7.

Wiring layout examples of respective layers of the four-layer circuit board are illustrated in FIGS. 3A to 4B. FIG. 3A is a layout of a first layer of the circuit board mounting devices, wherein a wiring pattern is configured to be customized to an electrode terminal arrangement of the mount devices. FIG. 3B is a layout of a second layer of the circuit board. A portion 3 corresponding to the ground pattern of power to be supplied to semiconductor components is largely widened, and a part 30 of the portion 3 is made to have a shape to be exposed to an end portion of the package when the package is singulated. FIG. 4A is a layout of a third layer of the circuit board. In the third layer, connections of the inside of the circuit board are made. FIG. 4B is a layout of a fourth layer of the circuit board. In the fourth layer, an electrode for connection for connecting between the circuit board and the mother board.

Also, a part of the ground pattern 3 is exposed to an outside surface at an end surface of the circuit board 1 in the state of the package, and the electromagnetic shielding layer 2 formed to the surface of the sealant 7 is electrically connected to the ground pattern 3 exposed to the outside surface.

The electromagnetic shielding layer 2 is formed by applying metal particles to the surface of the sealant 7 and the end surface of the circuit board 1 and sintering the same, and has a structure having holes between sintered particles. Further, an electrical bonding is made to the ground pattern 3 at the same time of the sintering.

The electromagnetic shielding layer 2 has a structure in which the electromagnetic shielding layer 2 is formed to a periphery of the sealant 7 and also the end surface of the circuit board 1, thereby shielding the mount devices 5 and 6 from noise of external electromagnetic waves.

In addition, since electromagnetic noise generated from the inside of the package of electronic components is not released to the outside in the same manner, no radio disturbance is given to other peripheral electronic components and electronic equipments.

The metal used in the metal sintered layer for forming the electromagnetic shielding layer 2 is gold (Au), silver (Ag), copper (Cu), or nickel (Ni) etc., and the electromagnetic shielding layer 2 having a sufficient electromagnetic wave shielding effect can be formed by using silver or a mixture of silver and copper in view of conductivity, cost, etc.

In FIG. 5, in the metal sintered layer formed by using silver as the metal particles, there are a large number of fine holes 8, and, moisture absorbed by an insulating resin which is the sealant 7 and/or the circuit board 1 becoming moisture vapor by heating is released to the outside of the package of electronic components through the holes 8.

Therefore, the vaporized moisture vapor does not remain at the interface of the sealant 7 and the electromagnetic shielding layer 2 and a pressure increase due to thermal expansion of the moisture vapor does not occur, and thus cracks do not occur in the electromagnetic shielding layer 2.

A relation of a hole diameter of the shielding layer to a level of electromagnetic waves and a permeation rate of moisture vapor measured through the shielding layer is illustrated in FIG. 6.

While a size of the hole 8 in the metal sintered layer differs depending on frequency of the electromagnetic wave to be shielded, as to frequencies from about 900 MHz to 2 GHz used for mobile phones can be shielded even by holes having a diameter of about 300 μm.

However, to stably ensure the shielding effect of electromagnetic waves in consideration of ununiformity of the thickness of the shielding layer, it is preferable to make the diameter smaller than or equal to 50 μm.

Meanwhile, there is a tendency that the larger the hole diameter, the higher the permeation rate of moisture vapor, and when the hole diameter is smaller than 0.1 μm, the permeation rate of moisture vapor is rapidly lowered. Therefore, a minimum hole diameter is preferable to be larger than or equal to 0.1 μm giving consideration to easiness for the vaporized moisture vapor to pass and the fact that a sintering agent etc. is prone to be vaporized in the sintering process of the metal particles.

By subjecting a junction material containing metal oxide particles having an average particle diameter of 1 nm to 50 μm, a acetic acid series compound or a formic acid series compound, and a reducing agent of an organic compound into a sintering in air atmosphere, the metal sintered layer can be obtained from the metal particles used for sintering.

By adding the reducing agent of an organic compound, a phenomenon is used that the metal particles are reduced at a low temperature, and metal particles having an average particle diameter of 100 nm or smaller are made upon the reduction, and the metal particles are mutually fused so that a sintering is done.

Since metal particles of 100 nm or smaller start to form in metal oxide particles at 200° C. or lower, sintering can be achieved at a low temperature at 200° C. or lower at which conventionally sintering has been difficult to make.

Also, since metal particles having a particle diameter of 100 nm or smaller are formed on the scene during the sintering, the metal particles enter fine portions of the surface of the sealant 7 without performing a processing etc. on the surface of the sealant 7, thereby ensuring a bonding strength of the sealant 7 and the electromagnetic shielding layer 2.

A reason of describing the average particle diameter of larger than or equal to 1 nm to smaller than or equal to 50 μm as the particle diameter of the metal particles is that, when the average particle diameter of the metal particles is larger than 50 μm, metal particles having a particle diameter of 100 nm or smaller are difficult to form during a bonding and thus voids among particles are increased and it becomes difficult to obtain a sintered layer.

Also, 1 nm or larger has been used because it is difficult to actually form metal particles having a particle diameter of 100 nm or smaller in the sintering process.

In the present embodiment, as metal particles having a particle diameter of 100 nm or smaller are formed in the sintering process, it is unnecessary to make the particle diameter of the metal particles smaller than or equal to 100 nm, and it is preferable to use a particle diameter of 1 to 50 μm in view of formation of metal particle precursor, handleability, and long-term storability.

As the metal oxide particles, there are silver oxide (Ag₂O, AgO) and/or copper oxide (CuO), and it is possible to use materials formed of at least one type of metal or two types of metals from groups of silver oxide and copper oxide.

Since metal oxide particles formed of silver oxide (Ag₂O, AgO) and/or copper oxide (CuO) generate only oxygen upon reduction, a residue after a sintering is hard to remain and also a decrease in volume is very small.

As the acetic acid series compound, there are silver acetate and copper acetate, and, as a formic acid series, there are silver formate and copper formate, and it is possible to use a bonding material formed of at least one type of metal or two or more types of metals from the groups of silver formate and copper formate.

A state in which the oxide particles mentioned above and acetic acid compound particles or formic acid compound particles are mixed is required.

As a contained amount of metal particles is preferable to be 99 parts exceeding 50 parts in total parts in the sintering material. This is because the more the contained amount of metal in the bonding material, the less an organic residue after a bonding at a low temperature, and thus it is possible to achieve a sintered layer and a metallic bonding (binding) at a sintered interface, and it is possible to increase strength of the electromagnetic shielding layer 2.

As the reducing agent of an organic compound, a mixture of one or more kinds from alcohol, carboxylic acids, and amine can be used.

As usable compounds containing alcohol group, there is alkyl alcohol, and, for example, there are ethanol, propanol, butyl alcohol, pentyl alcohol, hexyl alcohol, heptyl alcohol, octyl alcohol, nonyl alcohol, decyl alcohol, undecyl alcohol, dodecyl alcohol, tridecyl alcohol, tetradecyl alcohol, pentadecyl alcohol, hexadecyl alcohol, heptadecyl alcohol, octadecyl alcohol, nonadecyl alcohol, and icocyl alcohol.

Further, it is not limited to a primary alcohol type, and a secondary alcohol such as ethylene glycol, triethylene glycol, a tertiary alcohol, and alkanediol, and/or an alcohol compound having a cyclic structure can be used. In addition, a compound having four alcohol groups such as citric acid, ascorbic acid, etc. can be used.

Still further, as a usable compound containing carboxylic acid, there is alkylcarboxylic acid. As specific examples, there are butanoic acid, pentanoic acid, hexanoic acid, heptane acid, octane acid, nonanoic acid, decanoic acid, undecanoic acid, dodecanoic acid, tridecanoic acid, tetradecanoic acid, pentadecanoic acid, hexadecanoic acid, heptadecanoic acid, octadecanoic acid, nonadecanoic acid, and icosanoic acid.

Also, it is not limited to a primary carboxylic acid similar to the amino group, and a secondary carboxylic acid, tertiary carboxylic acid, and dicarboxylic acid, and/or a carboxyl compound having a cyclic structure can be used.

Still further, as a compound containing a usable amino group, alkylamine can be provided. For example, there are butyl amine, pentylamine, hexylamine, heptylamine, octylamine, nonylamine, decylamine, undecylamine, dodecylamine, tridecylamine, tetradecylamine, pentadecylamine, hexadecylamine, heptadecylamine, octadecylamine, nonadecylamine, and icocylamine.

Also, the compound having an amino group can have a branched structure, and there are examples of such a compound as 2-ethylhexylamine, 1,5-dimethylhexylamine, etc. Also, it is not limited to primary amine, and secondary amine and/or tertiary amine can be used. Further, as such an organic compound can have a cyclic structure.

Still further, the reducing agent to be used is not limited to above-mentioned organic compounds containing alcohol, carboxylic acid, and/or amine; and aldehyde group, ester group, sulfanilic group, ketone group, etc. can be used.

Here, reducing agents which are liquid at 20 to 30° C. such as ethylene glycol, triethylene glycol, etc. are reduced by silver after one day when they are mixed with silver oxide (Ag₂O) etc. and left, and thus it is necessary to use the reducing agent right after mixing.

Meanwhile, a reaction does not develop in myristyl alcohol, laurylamine, ascorbic acid, etc. even when they are left with a metal oxide etc. for about one month, and thus they are good at storability and it is preferable to use them when storing for a long time after mixing.

Still further, after reducing metal oxide etc., the reducing agent to be used is preferable to have a certain level of carbon number for working as a protective film of refined metal particles having a particle diameter of 100 nm or smaller. More specifically, the carbon number is preferable to be larger than or equal to 2 and smaller than or equal to 20. This is because, when the carbon number is smaller than 2, a growth in particle diameter occurs at the same time of forming the metal particles, and it becomes difficult to form metal particles of 100 nm or smaller.

Also, when the carbon number of larger than 20, decomposition temperature is increased and sintering of the metal particles becomes difficult to occur.

A used amount of the reducing agent is in a range of larger than or equal to 1 part and smaller than or equal to 50 parts to total parts of the metal particles. This is because, when the amount of the reducing agent is less than 1 part, the amount is insufficient to form fine metal particles by reducing all the metal particles in the joint material.

Also, when the amount exceeds 50 parts, a residue after jointing is increased, and it is difficult to achieve a metal joint at an interface and sintering in a jointed silver layer.

As a combination of metal particles and a reducing agent of an organic compound, there is no particular limitation as long as mixing of the metal particles and the reducing agent is capable of forming finer metal particles, and it is preferable to make a combination not forming metal particles at normal temperature in view of storability.

As described above, in the present embodiment, the electromagnetic shielding layer 2 of a metal thin film formed by sintering of metal particles is, in the same manner as the shielding layer of a metal cap, capable of shielding high-frequency waves transmitted from a high-frequency semiconductor element and also is capable of shielding high-frequency waves from other semiconductor devices.

Further, since the electromagnetic shielding layer 2 of a metal thin film is formed of a sintered compact of a metal, the electromagnetic shielding layer 2 has fine holes inside its thin-film layer, easily releasing moisture vapor from the insulating resin layer and/or the circuit board from the inside to the outside of the electromagnetic shielding layer 2 in a metal thin film in a manufacturing process of a semiconductor device, thereby preventing exfoliation at an interface of the sealant 7 of an insulating resin for sealing provided around the mount devices 5 and 6 and the electromagnetic shielding layer 2 of a metal thin film, and preventing cracks of the electromagnetic shielding layer 2 of a metal thin film.

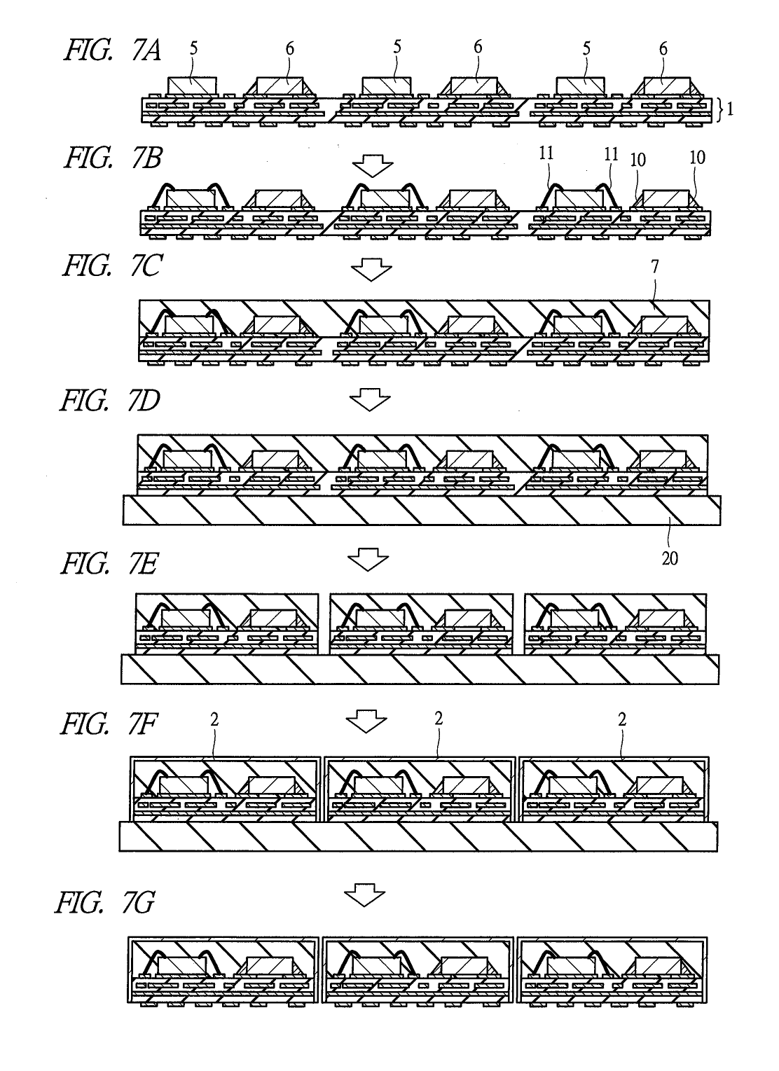

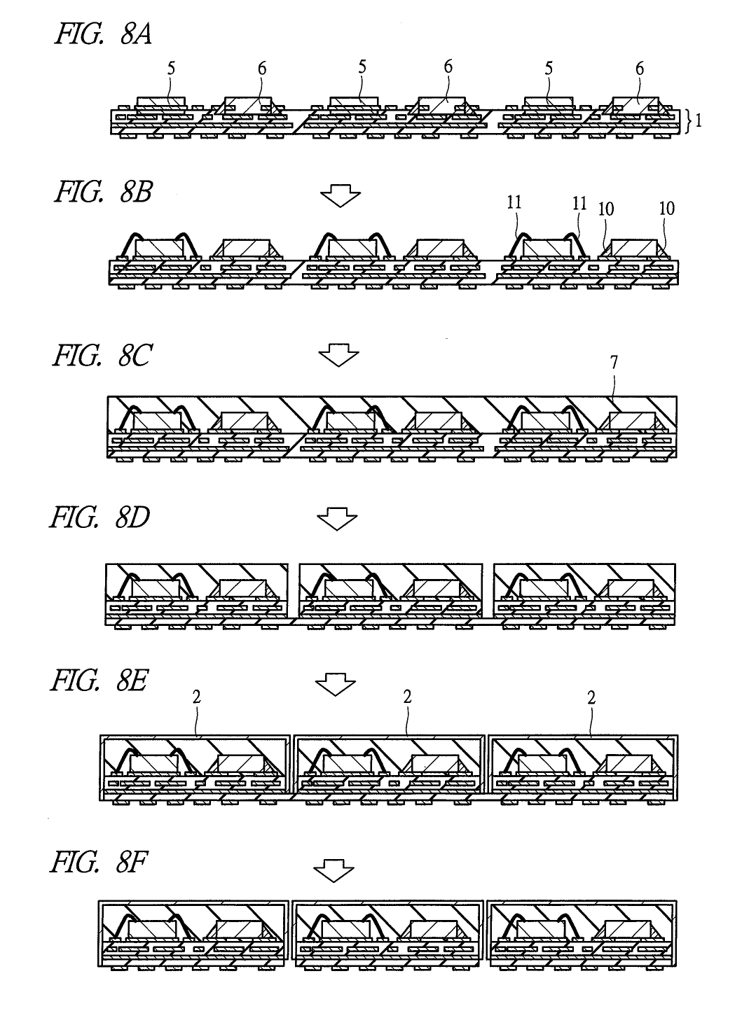

Next, with reference to FIGS. 7A to 8F, a method of manufacturing the semiconductor device according to the embodiment of the present invention will be described. FIGS. 7A to 8F are diagrams illustrating the method of manufacturing the semiconductor device according to the embodiment of the present invention, where an adhesive film for cutting/holding is fixed to a bottom surface of the circuit board 1 in FIG. 7A to 7G, and the bottom surface of the circuit board 1 is fixed by the circuit board 1 after cutting the circuit board 1 until the ground layer in FIGS. 8A to 8F.

First, as illustrated in FIG. 7A, the mount devices 5 and 6 such as elements are mounted on the circuit board 1, and, as illustrated in FIG. 7B, the mount devices 5 and 6 on the circuit board are electrically connected using a plating 10, wires 11, etc.

Then, as illustrated in FIG. 7C, the top surface of the circuit board 1 is sealed by the sealant 7 such as a sealing resin, and, as illustrated in FIG. 7D, an adhesive tape 20 for cutting/holding is fixed to the bottom surface of the circuit board 1.

Then, as illustrated in FIG. 7E, sealed portions of the sealant 7 and the circuit board 1 are cut and divided in a unit of an electronic component package to be a semiconductor device.

Then, as illustrated in FIG. 7F, for example, metal particles (liquid) are applied by an ink-jet manner etc., and sintered to be hardened so that the electromagnetic shielding layer 2 is formed.

Then, as illustrated in FIG. 7G, the adhesive tape 20 is peeled off, thereby separating each package of electronic components.

In addition, when not using the adhesive tape 20, the process is in the same manner as FIGS. 7A to 7C until the top surface of the circuit board 1 is sealed by the sealant 7 such as a sealing resin illustrated in FIGS. 8A to 8C, and thereafter, as illustrated in FIG. 8D, cutting is performed until sealed parts of the sealant 7 and a part of the circuit board (ground layer) in a unit of a package of electronic components to be a semiconductor device.

Then, as illustrated in FIG. 8E, for example, metal particles (liquid) are applied by an ink-jet manner and sintered to be hardened so that the electromagnetic shielding layer 2 is formed.

Then, as illustrated in FIG. 8F, the circuit board 1 is cut again so that each package of electronic components is separated.

As described above, by manufacturing semiconductor devices, the electromagnetic shielding layer 2 is formed by sintering a mixture of metal particles or metal oxide particles, an acetic acid compound or a formic acid compound, and a reducing agent of an organic compound, thereby forming a metal thin film layer without largely changing a conventional manufacturing process of a semiconductor device.

Also, processings like plating are not performed, and thus, as in FIGS. 8A to 8F, semiconductor devices can be manufactured without using an adhesive film to protect the bottom surface of the circuit board 1.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention relates to a semiconductor device and is widely applicable to semiconductor-mounting electronic components which require a shielding structure for avoiding adverse effects of peripheral radio waves and/or electromagnetic noise from semiconductors, and semiconductor devices mounting high-frequency semiconductor elements from which noise generated from the high-frequency semiconductor elements themselves is required to be shielded.

### DESCRIPTIONS OF REFERENCE NUMERALS

1 . . . Circuit board; 2 . . . Electromagnetic wave shielding layer; 3 . . . Ground pattern; 4 . . . Wiring pattern; 5 and 6 . . . Mount devices; 7 . . . Sealant; 8 . . . hole; 10 . . . Plating; 11 . . . Wire; 12 . . . Via hole; and 20 . . . Adhesive tape.

1. A semiconductor device comprising:
a circuit board having two or more wiring layers;
electronic components mounted on the circuit board and connected to a pad of the wiring layer of a top surface of the circuit board;
a sealant sealing the electronic components on the circuit board by an insulating resin; and
an electromagnetic shielding layer formed by applying metal particles to a surface of the sealant and sintering the metal particles applied,
the electromagnetic shielding layer being electrically connected to one of the wiring layers of the circuit board.

2. The semiconductor device according to claim 1,
wherein the electromagnetic shielding layer is formed by sintering of silver or metal particles formed of silver and copper.

3. The semiconductor device according to claim 1,
wherein the electromagnetic shielding layer has a plurality of holes of larger than or equal to 0.1 μm and smaller than or equal to 50 μm formed by the sintering.

4. The semiconductor device according to claim 1,
wherein the electromagnetic shielding layer is formed by a sintering of a mixture of metal oxide particles, an acetic acid compound or a formic acid compound, and a reducing agent of an organic compound.

5. A method of manufacturing a semiconductor device comprising the steps of:
mounting electronic components on a circuit board having two or more wiring layers;
connecting the electronic components to a pad of the wiring layer at a top surface of the circuit board;
sealing the electronic components on the circuit board by a sealant of an insulating resin;
applying metal particles to a surface of the sealant, sintering the metal particles applied to be electrically connected to one of the wiring layers of the circuit board.
